(19) United States
(12) Patent Application Publication
(10) Pub. No.: US 2025/0203877 A1
(43) Pub. Date: Jun. 19, 2025

(54) MAGNETIC MEMORY DEVICE INCLUDING TUNNELING MAGNETORESISTANCE LAYER AND MEMORY DEVICE INCLUDING THE MAGNETIC MEMORY DEVICE

(71) Applicant: Samsung Electronics Co., Ltd., Suwon-si (KR)

(72) Inventors: Kwangseok KIM, Suwon-si (KR); Naoki HASE, Suwon-si (KR); Soichiro MIZUSAKI, Suwon-si (KR); Jungsik PARK, Suwon-si (KR)

(73) Assignee: Samsung Electronics Co., Ltd., Suwon-si (KR)

(21) Appl. No.: 18/978,486

(22) Filed: Dec. 12, 2024

(30) Foreign Application Priority Data
Dec. 18, 2023 (KR) 10-2023-0185090
Jul. 11, 2024 (KR) 10-2024-0091822

(51) Int. Cl. H10B 61/00; H01F 10/32; H10N 50/10; H10N 50/85

(52) U.S. Cl. CPC H10B 61/20; H01F 10/329; H10N 50/10; H10N 50/85

(57) ABSTRACT

A magnetic memory device including a tunneling magnetoresistance layer and a memory device including the magnetic memory device are provided. The magnetic memory device includes the tunneling magnetoresistance layer, including a free layer, a tunneling barrier layer, and a pinned layer, and a spin orbit torque (SOT) layer configured to provide a spin current to change a magnetization direction of the free layer of the tunneling magnetoresistance layer, wherein the SOT layer includes an orbital Hall conductance (OHC) material layer configured to provide an orbital Hall current and a conversion layer configured to convert the orbital Hall current of the OHC material layer into the spin current, and the OHC material layer includes at least one material of iridium (Ir), manganese (Mn), vanadium (V), chromium (Cr), niobium (Nb), molybdenum (Mo), ruthenium (Ru), tantalum (Ta), tungsten (W), and rhenium (Re), or an alloy thereof.

### CROSS-REFERENCE TO RELATED APPLICATION

This application is based on and claims priority under 35 U.S.C. § 119 to Korean Patent Application Nos. 10-2023-0185090 filed on Dec. 18, 2023, and 10-2024-0091822 filed on Jul. 11, 2024, in the Korean Intellectual Property Office, the disclosures of which are incorporated by reference herein in their entireties.

### BACKGROUND

### 1. Field

The disclosure relates to magnetic memory devices including tunneling magnetoresistance layers and memory devices including the magnetic memory devices.

### 2. Description of the Related Art

A magnetic memory device such as magnetic random-access memory (MRAM) stores data by using a change in the resistance of a magnetic tunneling junction device. The resistance of the magnetic tunneling junction device varies with the relative magnetization direction of a free layer. For example, when the magnetization direction of the free layer is the same as the magnetization direction of a pinned layer, the magnetic tunneling junction device may have a lower resistance, and when the magnetization directions are opposite to each other, the magnetic tunneling junction device may have a higher resistance. When this characteristic is used in a memory device, for example, a magnetic tunneling junction device having a lower resistance may correspond to data ‘0’ and a magnetic tunneling junction device having a higher resistance may correspond to data ‘1’.

Such a magnetic memory device has advantages such as non-volatility, higher-speed operation, and/or higher durability. For example, spin transfer torque-magnetic RAM (STT-MRAM) that is currently mass-produced may have an operating speed of about 50 nanoseconds (nsec) to 100 nsec and also may have excellent data retention, e.g., of 10 years or more. In addition, spin orbit torque (SOT)-MRAM may have a very high operation speed less than or equal to 5 nsec, which is faster than the STT-MRAM because a spin polarization direction is perpendicular to the magnetization direction. Moreover, the SOT-MRAM may have more stable characteristics because a path of a write current and a path of a read current are different from each other.

### SUMMARY

Provided are a magnetic memory device including a tunneling magnetoresistance layer and a memory device including the magnetic memory device.

Additional aspects will be set forth in part in the description which follows and, in part, will be apparent from the description, or may be learned by practice of the presented embodiments of the disclosure.

According to an aspect of at least one embodiment, a magnetic memory device including a tunneling magnetoresistance layer including a free layer, a tunneling barrier layer, and a pinned layer, and a spin orbit torque (SOT) layer configured to provide a spin current, the spin current configured to change a magnetization direction of the free layer of the tunneling magnetoresistance layer, wherein the SOT layer includes an orbital Hall conductance (OHC) material layer configured to provide an orbital Hall current, and a conversion layer configured to convert the orbital Hall current into the spin current, and the OHC material layer includes at least one material of iridium (Ir), manganese (Mn), vanadium (V), chromium (Cr), niobium (Nb), molybdenum (Mo), ruthenium (Ru), tantalum (Ta), tungsten (W), or rhenium (Re).

The OHC material layer may include at least one of IrMn or PtMn.

The conversion layer may include at least one of platinum (Pt), terbium (Tb), gadolinium (Gd), samarium (Sm), or dysprosium (Dy).

The conversion layer may be between the OHC material layer and the tunneling magnetoresistance layer, and the free layer of the tunneling magnetoresistance layer may be between the conversion layer and the tunneling barrier layer.

The SOT layer may further include an in-plane magnetic anisotropy layer between the OHC material layer and the conversion layer, the free layer and the pinned layer may each have perpendicular magnetic anisotropy (PMA), and the in-plane magnetic anisotropy layer may have in-plane magnetic anisotropy.

The in-plane magnetic anisotropy layer may include at least one of cobalt (Co), iron (Fe), nickel (Ni), CoFe, FeB, CoFeB, or CoB.

The SOT layer may further include an insertion layer between the conversion layer and the tunneling magnetoresistance layer, and the insertion layer may include at least one of tungsten (W), tantalum (Ta), molybdenum (Mo), rhenium (Re), iridium (Ir), or ruthenium (Ru).

The SOT layer may further include a spin Hall conductance (SHC) material layer configured to generate the spin current due to a spin Hall effect, the SHC material layer may be provided between the OHC material layer and the conversion layer, the OHC material layer may include chromium (Cr), and the SHC material layer may include at least one of tungsten (W) or tungsten (βW) with a beta (β) phase.

The SOT layer may further include a SHC material layer configured to generate the spin current due to a spin Hall effect, the conversion layer is between the SHC material layer and the OHC material layer, the OHC material layer may include chromium (Cr), and the SHC material layer may include at least one of tungsten (W) or tungsten (βW) with a beta (B) phase.

The SOT layer may further include a seed layer configured to promote the beta (B) phase in the SHC material layer.

The seed layer may include at least one material of TaN, MgO, or CoFeB.

The free layer may include a first free layer, a second free layer, and an antiferromagnetic coupling layer between the first free layer and the second free layer, and a magnetization direction of the first free layer may be opposite to a magnetization direction of the second free layer.

The antiferromagnetic coupling layer may include at least one of ruthenium (Ru), iridium (Ir), tantalum (Ta), tungsten (W), palladium (Pd), zirconium (Zr), platinum (Pt), or aluminum (Al).

The magnetic memory device may further include a first electrode and a second electrode spaced apart from each other, the first electrode and second electrode configured to provide a write current between the first electrode and second electrode and through the SOT layer, and a third electrode electrically connected to the pinned layer such that the third electrode and at least one of the first electrode or the second electrode are configured to provide a read current through the tunneling magnetoresistance layer and the SOT layer.

According to an aspect of at least one embodiment, a memory device including a plurality of memory cells each including a magnetic memory device and a switching device connected to the magnetic memory device, wherein the magnetic memory devices includes a tunneling magnetoresistance layer including a free layer, a tunneling barrier layer, and a pinned layer, and a spin orbit torque (SOT) layer configured to provide a spin current, the spin current configured to change a magnetization direction of the free layer of the tunneling magnetoresistance layer, wherein the SOT layer includes an OHC material layer configured to provide an orbital Hall current, and a conversion layer configured to convert the orbital Hall current of the OHC material layer into the spin current, and the OHC material layer includes at least one of iridium (Ir), manganese (Mn), vanadium (V), chromium (Cr), niobium (Nb), molybdenum (Mo), ruthenium (Ru), tantalum (Ta), tungsten (W), or rhenium (Re).

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view illustrating a schematic configuration of a magnetic memory device according to at least one embodiment;

FIG. 2 is a cross-sectional view illustrating a schematic configuration of a magnetic memory device according to at least one embodiment;

FIG. 3 is a graph showing a change in a spin Hall angle (SHA) according to a thickness of a conversion layer in a spin orbit torque (SOT) layer shown in FIG. 1;

FIG. 4 is a graph showing a change in the SHA according to the thickness of the conversion layer in the SOT layer shown in FIG. 2;

FIG. 5 is a graph showing an operating current of the magnetic memory device shown in FIG. 2;

FIG. 6 is a cross-sectional view illustrating a schematic configuration of a magnetic memory device according to at least one embodiment;

FIG. 7 is a cross-sectional view illustrating a schematic configuration of a magnetic memory device according to at least one embodiment;

FIG. 8 is a cross-sectional view illustrating a schematic configuration of a magnetic memory device according to at least one embodiment;

FIG. 9 is a cross-sectional view illustrating a schematic configuration of a magnetic memory device according to at least one embodiment;

FIG. 10 is a cross-sectional view illustrating a schematic configuration of a magnetic memory device according to at least one embodiment;

FIG. 11 is a cross-sectional view illustrating a schematic configuration of a magnetic memory device according to at least one embodiment;

FIG. 12 schematically shows one magnetic memory cell including a magnetic memory device according to at least one embodiment;

FIG. 13 is a circuit diagram schematically illustrating a configuration of a memory device including a plurality of memory cells shown in FIG. 12; and

FIG. 14 is a conceptual diagram schematically illustrating a device architecture applicable to an electronic device.

### DETAILED DESCRIPTION

Reference will now be made in detail to embodiments, examples of which are shown in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, with reference to the accompanying drawings, a magnetic memory device including a tunneling magnetoresistance layer and a memory device including the magnetic memory device will be described in detail. Like reference numerals refer to like elements throughout, and in the drawings, sizes of elements may be exaggerated for clarity and convenience of explanation. The embodiments described below are merely examples, and various modifications may be possible from the embodiments.

In a layer structure described below, an expression “on/below” may include not only “immediately on/below in a contact manner” but also “on/below in a non-contact manner”. It will also be understood that spatially relative terms, such as “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly. An expression used in the singular encompasses the expression of the plural, unless it has a clearly different meaning in the context. It will be further understood that the terms “comprises” and/or “comprising” used herein specify the presence of stated features or elements, but do not preclude the presence or addition of one or more other features or elements.

The use of “the” and other demonstratives similar thereto may correspond to both a singular form and a plural form. Unless the order of operations of a method according to the disclosure is explicitly mentioned or described otherwise, the operations may be performed in a proper order. The disclosure is not limited to the order the operations are mentioned.

The functional elements, including those indicated by terms such as “unit” or “module”, indicates a unit for processing at least one function or operation, and may be implemented in processing circuitry, such as hardware or software, or in a combination of hardware and software. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc., and/or electronic circuits including said components.

The connecting lines, or connectors shown in the various figures presented are intended to represent functional relationships and/or physical or logical couplings between the various elements. It should be noted that many alternative or additional functional relationships, physical connections or logical connections may be present in a practical device.

The use of any and all examples, or language provided herein, is intended merely to better illuminate the disclosure and does not pose a limitation on the scope of the disclosure unless otherwise claimed. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometric. When referring to “C to D”, this means C inclusive to D inclusive unless otherwise specified.

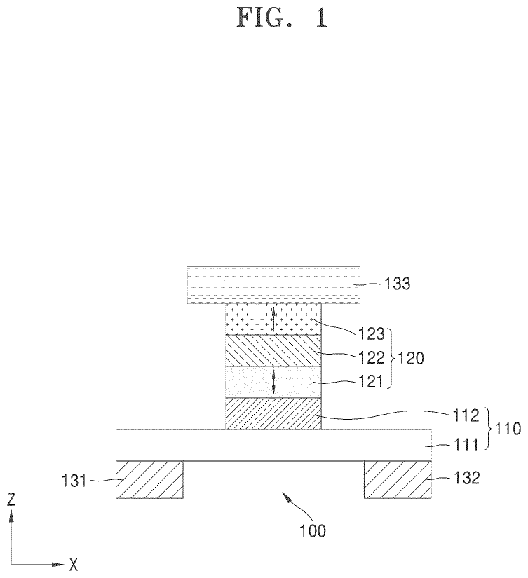

FIG. 1 is a cross-sectional view illustrating a schematic configuration of a magnetic memory device 100 according to at least one embodiment. Referring to FIG. 1, the magnetic memory device 100 according to at least one embodiment includes a spin orbit torque (SOT) layer 110 and a tunneling magnetoresistance layer 120 provided on the SOT layer 110.

The tunneling magnetoresistance layer 120 may include a free layer 121 provided on the SOT layer 110, a tunneling barrier layer 122 provided on the free layer 121, and a pinned layer 123 provided on the tunneling barrier layer 122. The expression “provided on” is for convenience of explanation and does not necessarily mean a top-down relationship. To put it another way, the free layer 121 and the pinned layer 123 may face each other, and the tunneling barrier layer 122 may be provided between the free layer 121 and the pinned layer 123. Also, the tunneling magnetoresistance layer 120 may be provided such that the free layer 121 is in direct contact with the SOT layer 110 and/or such that the free layer 121 is provided between the tunneling barrier layer 122 and the SOT layer 110.

The free layer 121 and the pinned layer 123 may each include a ferromagnetic metal material having magnetism. For example, the free layer 121 and the pinned layer 123 may each include a ferromagnetic material including at least one of iron (Fe), cobalt (Co), nickel (Ni), manganese (Mn), a Fe-containing alloy, a Co-containing alloy, a Ni-containing alloy, a Mn-containing alloy, and/or a Heusler alloy (or “Heusler compound”). The free layer 121 and the pinned layer 123 may each include the same ferromagnetic material, but are not limited thereto. In addition, the free layer 121 may further include boron (B) to improve wetting characteristics of the free layer 121 in a process of depositing the free layer 121. For example, the free layer 121 may include CoFeB.

In addition, the free layer 121 and the pinned layer 123 may each be configured to have high perpendicular magnetic anisotropy (PMA). In other words, PMA energy of each of the free layer 121 and the pinned layer 123 may exceed out-of-plane magnetization energy. In this case, a magnetic moment of each of the free layer 121 and the pinned layer 123 may be stabilized in a thickness direction (e.g., a Z direction) or in a direction perpendicular to a plane direction (e.g., an X direction).

The pinned layer 123 may have a pinned magnetization direction. Once determined, the magnetization direction of the pinned layer 123 may not be changed during the operation and/or lifetime of the magnetic memory device 100. On the other hand, the free layer 121 may have a variable magnetization direction. The tunneling magnetoresistance layer 120 may have a relatively low resistance when the magnetization directions of the free layer 121 and the pinned layer 123 are the same (e.g., parallel), and may have a relatively high resistance when the magnetization directions of the free layer 121 and the pinned layer 123 are opposite (e.g., anti-parallel). This phenomenon is called tunneling magnetoresistance (TMR).

The free layer 121 may have a relatively low saturation magnetization (Ms) such that the magnetization direction may be easily changed (e.g., switched). To this end, the free layer 121 may be doped with at least one non-magnetic metal as a dopant. The dopant may include, for example, at least one of magnesium (Mg), ruthenium (Ru), iridium (Ir), titanium (Ti), zinc (Zn), gallium (Ga), tantalum (Ta), aluminum (Al), molybdenum (Mo), zirconium (Zr), tin (Sn), tungsten (W), antimony (Sb), vanadium (V), niobium (Nb), chromium (Cr), germanium (Ge), silicon (Si), hafnium (Hf), terbium (Tb), scandium (Sc), yttrium (Y), rhodium (Rh), indium (In), calcium (Ca), strontium (Sr), barium (Ba), beryllium (Be), vanadium (V), lithium (Li), cadmium (Cd), palladium (Pb), and/or gallium (Ga). A doping concentration of the non-magnetic metal in the free layer 121 may be in a range of, for example, about 5 at % to about 50 at %.

The tunneling barrier layer 122 may serve as a tunnel barrier for a magnetic tunneling junction. The tunneling barrier layer 122 may include crystalline magnesium (Mg) oxide. For example, the tunneling barrier layer 122 may include at least one of MgO, MgAl₂O₄, and/or MgTiOₓ (wherein x represents an integer).

The free layer 121 is configured such that the magnetization direction of the free layer 121 may be changed by a SOT generated due to a spin current generated in the spin orbit torque layer 110. In this regard, the magnetic memory device 100 may be applied to a SOT magnetic random-access memory (MRAM). The SOT layer 110 may switch the magnetization direction of the free layer 121 by providing the spin current to the tunneling magnetoresistance layer 120, especially the free layer 121, according to the current flowing through the SOT layer 110. For example, the free layer 121 may be magnetized in a +Z direction or a −Z direction according to a direction of the current applied to the SOT layer 110.

According to at least one embodiment, the SOT layer 110 may be configured to lower an operating current density for switching the magnetization direction of the free layer 121. To this end, the SOT layer 110 may generate a relatively large spin current even with a relatively low operating current density. The amount of spin current generated in the SOT layer 110 may increase as a spin Hall angle (SHA), which is the efficiency at which a charge current is converted into the spin current by the spin Hall effect, increases, and a spin Hall conductance (SHC) of the SOT layer 110 itself by the spin Hall effect increases.

Among the currently known materials, platinum (Pt) is a material with high SHA and SHC, but platinum (Pt) alone has limitations in increasing the SHC. According to at least one embodiment, the amount of spin current generated in the SOT layer 110 may be increased by using a material with an orbital Hall conductance (OHC) greater than the SHC of platinum (Pt) and a material converting an OHC of the material into the SHC together, based on the fact that there is a material whose OHC obtained by an orbital Hall effect is greater than the SHC of platinum (Pt).

For example, the SOT layer 110 may include an OHC material layer 111 that provides an orbital Hall current and a conversion layer 112 that converts the orbital Hall current into the spin current. The conversion layer 112 may be provided on the OHC material layer 111, and the tunneling magnetoresistance layer 120 may be provided on the conversion layer 112. In other words, the conversion layer 112 may be provided between the OHC material layer 111 and the tunneling magnetoresistance layer 120, particularly between the OHC material layer 111 and the free layer 121. In at least one embodiment, the free layer 121 of the tunneling magnetoresistance layer 120 is provided to be in direct contact with the conversion layer 112.

The OHC material layer 111 may include an element having a relatively large OHC and/or an alloy thereof. For example, the OHC material layer 111 may include at least one of iridium (Ir), manganese (Mn), vanadium (V), chromium (Cr), niobium (Nb), molybdenum (Mo), ruthenium (Ru), tantalum (Ta), tungsten (W), rhenium (Re), and/or an alloy thereof. For example, the alloy may include IrMn and/or PtMn. A thickness of the OHC material layer 111 may be, for example, about 1 nanometers (nm) or more and/or about 10 nm or less. For example, the thickness of the OHC material layer 111 may be within a range of about 3 nm to about, and/or about 4 nm to about 6 nm.

The conversion layer 112 may include, for example, platinum (Pt) and/or at least one rare earth element among terbium (Tb), gadolinium (Gd), samarium (Sm), and/or dysprosium (Dy). A thickness of the conversion layer 112 may be about 0.1 nm or more and/or about 5 nm or less. For example, thickness of the conversion layer 112 may be within of a range of about 0.5 nm to about 4 nm, and/or about 1 nm to about 3 nm.

According to at least one embodiment, the orbital Hall current may be generated in the OHC material layer 111 when a current is applied to the OHC material layer 111 including a material having a relatively large OHC. The orbital Hall current may be converted into the spin current by the conversion layer 112. In addition, because the current also flows in the conversion layer 112, a spin current may also be generated by the spin Hall effect in the conversion layer 112 itself. Therefore, the SOT layer 110 according to at least one embodiment may generate a large spin current compared to a case in which platinum (Pt) is used alone. Then, even if the current applied to the SOT layer 110 is relatively small, a spin current sufficient to perform magnetic switching on the free layer 121 of the tunneling magnetoresistance layer 120 may be obtained, and the operating current density of the magnetic memory device 100 may be reduced.

The magnetic memory device 100 may further include a first electrode 131 and a second electrode 132 for applying a current to the SOT layer 110. The first electrode 131 and the second electrode 132 may be spaced apart from each other on a lower surface of the SOT layer 110, particularly on a lower surface of the OHC material layer 111. When a voltage is applied to each of the first electrode 131 and the second electrode 132, the orbital Hall current may be generated while a current flows in the OHC material layer 111. Also, the magnetic memory device 100 may include a third electrode 133 for reading the resistance of the tunneling magnetoresistance layer 120. The third electrode 133 may be electrically connected to the pinned layer 123. Thereby, a current may be supplied between the first electrode 131 and the second electrode 132 during a write operation, and between the third electrode 133 and at least one of the first electrode 131 and the second electrode 132 during a read operation, as discussed in further detail below.

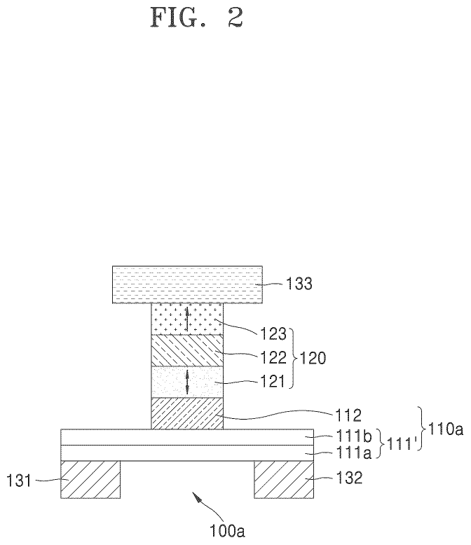

FIG. 2 is a cross-sectional view illustrating a schematic configuration of a magnetic memory device 100a according to at least one embodiment. FIG. 1 shows that the OHC material layer 111 has a single layer structure, but the OHC material layer 111 may have a multilayer structure in which different materials of the OHC material layer 111 are provided to different layers, respectively.

Referring to FIG. 2, a SOT layer 110a of the magnetic memory device 100a according to at least one embodiment may include an OHC material layer 111′ having a multilayer structure. For example, the OHC material layer 111′ may include a first layer 111a and a second layer 111b provided on the first layer 111a. The conversion layer 112 may be disposed on the second layer 111b. The first layer 111a and the second layer 111b may each include at least one material different from each other among iridium (Ir), manganese (Mn), vanadium (V), chromium (Cr), niobium (Nb), molybdenum (Mo), ruthenium (Ru), tantalum (Ta), tungsten (W), and/or rhenium (Re). For example, the first layer 111a may include iridium (Ir) and the second layer 111b may include manganese (Mn); or conversely, the first layer 111a may include manganese (Mn) and the second layer 111b may include iridium (Ir). Alternatively, one of the first layer 111a and the second layer 111b may include platinum (Pt) and the other may include at least one of iridium (Ir), manganese (Mn), vanadium (V), chromium (Cr), niobium (Nb), molybdenum (Mo), ruthenium (Ru), tantalum (Ta), tungsten (W), and/or rhenium (Re). For example, the first layer 111a may include platinum (Pt) and the second layer 111b may include manganese (Mn); or conversely, the first layer 111a may include manganese (Mn) and the second layer 111b may include platinum (Pt).

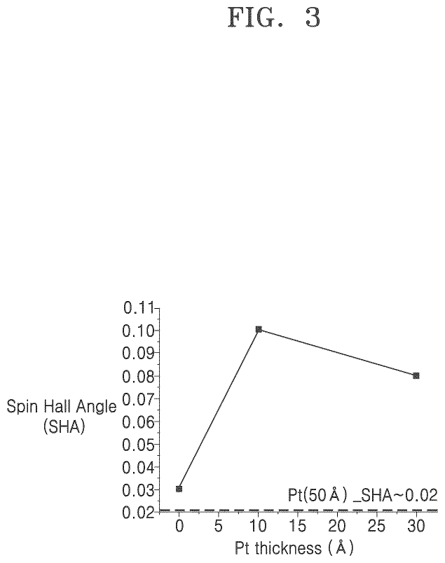

FIG. 3 is a graph showing a change in a SHA according to a thickness of the conversion layer 112 in the SOT layer 110 shown in FIG. 1. In the graph of FIG. 3, the horizontal axis represents the thickness of the conversion layer 112 and the vertical axis represents the SHA. The SHA has a dimensionless value with no unit. In FIG. 3, the OHC material layer 111 includes iridium (Ir), and the OHC material layer 111 has a thickness of 5 nm. Also, the conversion layer 112 includes platinum (Pt). Referring to the graph of FIG. 3, when the thickness of the conversion layer 112 is 10 Å (1 nm), the SHA is about 0.1, and when the thickness of the conversion layer 112 is 30 Å (3 nm), the SHA is about 0.08. Therefore, it may be seen that the SHA of the SOT layer 110 according to the example is much greater than 0.02 which is the SHA (indicated by a dotted line) when only platinum (Pt) having a thickness of 50 Å (5 nm) is used alone.

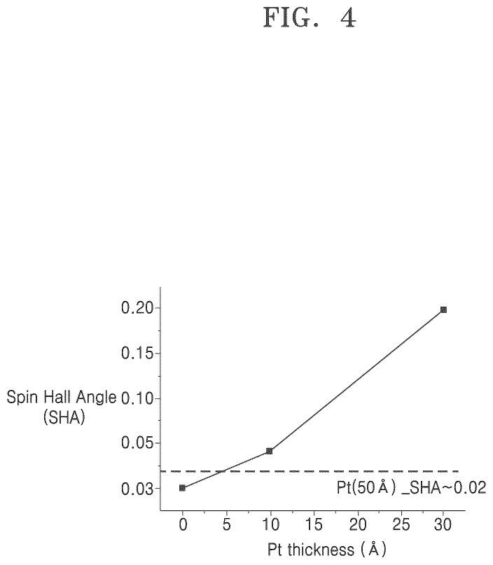

FIG. 4 is a graph showing a change in the SHA according to a thickness of the conversion layer 112 in the SOT layer 110a shown in FIG. 2. In FIG. 4, the first layer 111a of the OHC material layer 111′ includes iridium (Ir), the second layer 111b includes manganese (Mn), and an entire thickness of the OHC material layer 111′ is 5 nm. Also, the conversion layer 112 includes platinum (Pt). Referring to the graph of FIG. 4, when the thickness of the conversion layer 112 is 10 Å (1 nm), a SHA is about 0.05, and when the thickness of the conversion layer 112 is 30 Å (3 nm), the SHA is about 0.2. Therefore, it may be seen that the SHA of the SOT layer 110a according to the example is much greater than 0.02 which is the SHA (indicated by a dotted line) when only platinum (Pt) having a thickness of 50 Å (5 nm) is used alone. In addition, when the thickness of the conversion layer 112 increases to 3 nm, the SHA of the SOT layer 110a may increase significantly compared to the graph of FIG. 3.

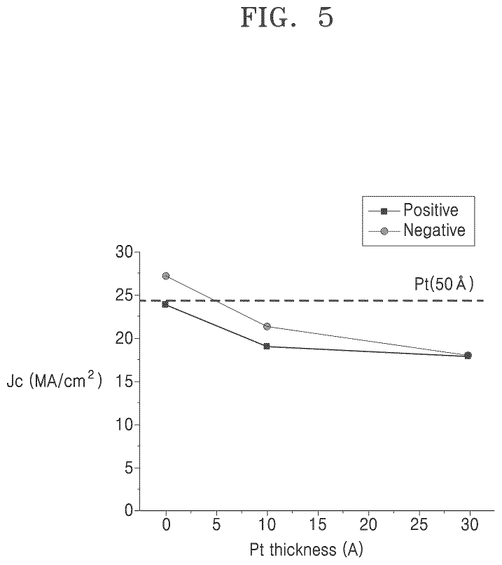

FIG. 5 is a graph showing an operating current of the magnetic memory device 100a shown in FIG. 2. In FIG. 5, the first layer 111a of the OHC material layer 111′ includes iridium (Ir), the second layer 111b includes manganese (Mn), and an entire thickness of the OHC material layer 111′ is 5 nm. Also, the conversion layer 112 includes platinum (Pt). In FIG. 5, a graph indicated by the black quadrangle ‘▪’ is a threshold current density for performing magnetic switching on the free layer 121 in the +Z direction, and a graph indicated by the black circle ‘●’ is a threshold current density for performing magnetic switching on the free layer 121 in the −Z direction. Referring to the graph of FIG. 5, it may be seen that when a thickness of the conversion layer 112 is 10 Å (1 nm) and 30 Å (3 nm), the threshold current density is lower than in a case where only platinum (Pt) having a thickness of 50 Å (5 nm) is used (indicated by a dotted line). For example, when the thickness of the conversion layer 112 is 30 Å (3 nm), the threshold current density of the magnetic memory device 100a is about 19 MA/cm², whereas the threshold current density of a comparative magnetic memory device using platinum (Pt) alone is about 25 MA/cm².

As described above, because the magnetic memory devices 100 and 100a according to the example embodiments perform magnetic switching on the free layer 121 by using the SOT, the magnetic memory devices 100 and 100a may each have a higher operation speed than a magnetic memory device using only a spin-transfer torque (STT). For example, the magnetic memory devices 100 and 100a according to the example embodiments may have a relatively high operation speed of about 5 nsec or less and/or about 1 nsec or less. In addition, because the magnetic memory devices 100 and 100a according to the example embodiments may operate at a relatively low current density while having the high operation speed, the magnetic memory devices 100 and 100a may each have a relatively low power consumption.

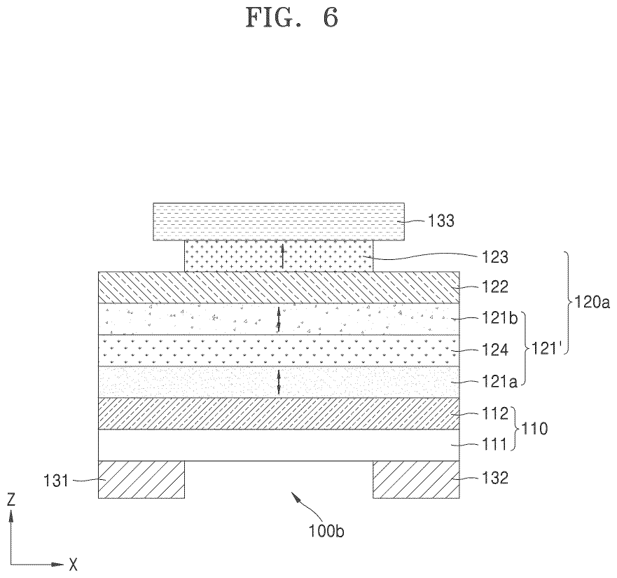

FIG. 6 is a cross-sectional view illustrating a schematic configuration of a magnetic memory device 100b according to at least one embodiment. Referring to FIG. 6, the magnetic memory device 100b may include the SOT layer 110 and a tunneling magnetoresistance layer 120a provided on the SOT layer 110. The tunneling magnetoresistance layer 120a may include a free layer 121′ provided on the SOT layer 110, the tunneling barrier layer 122 provided on the free layer 121′, and the pinned layer 123 provided on the tunneling barrier layer 122. FIG. 6 illustrates that the magnetic memory device 100b includes the SOT layer 110 shown in FIG. 1, but the examples of FIG. 6 are not limited thereto, and, e.g., the magnetic memory device 100b may include the SOT layer 110a shown in FIG. 2.

The free layer 121′ may have a structure of a synthetic antiferromagnet. For example, the free layer 121′ may include a first free layer 121a, an antiferromagnetic coupling layer 124 provided on the first free layer 121a, and a second free layer 121b provided on the antiferromagnetic coupling layer 124. In other words, the first free layer 121a and the second free layer 121b may face each other, and the antiferromagnetic coupling layer 124 may be provided between the first free layer 121a and the second free layer 121b. The first free layer 121a may be provided adjacent to the SOT layer 110, and the second free layer 121b may be provided adjacent to the tunneling barrier layer 122.

The first free layer 121a and the second free layer 121b may each include the ferromagnetic metal material described above. For example, the first free layer 121a and the second free layer 121b may each include at least one ferromagnetic material including iron (Fe), cobalt (Co), nickel (Ni), manganese (Mn), a Fe-containing alloy, a Co-containing alloy, a Ni-containing alloy, a Mn-containing alloy, and/or a Heusler alloy. The first free layer 121a and the second free layer 121b may each include the same ferromagnetic material, but are not limited thereto. In addition, at least one of the first free layer 121a and the second free layer 121b may further include boron (B) to improve wetting characteristics. In addition, at least one of the first free layer 121a and the second free layer 121b may be doped with at least one non-magnetic metal. The dopant may include, for example at least one of Mg, Ru, Ir, Ti, Zn, Ga, Ta, Al, Mo, Zr, Sn, W, Sb, V, Nb, Cr, Ge, Si, Hf, Tb, Sc, Y, Rh, In, Ca, Sr, Ba, Be, V, Li, Cd, Pb, and/or Ga and may be selected based the ferromagnetic material to reduce the saturation magnetization of the corresponding first free layer 121a and the second free layer 121b. For example, the first free layer 121a may include cobalt (Co) and/or CoNi, and the second free layer 121b may include CoFeB.

The antiferromagnetic coupling layer 124 may include a non-magnetic metal that generates a Dzyaloshinskii-Moriya interaction at an interface with the first free layer 121a and at an interface with the second free layer 121b. For example, the antiferromagnetic coupling layer 124 may include at least one of ruthenium (Ru), iridium (Ir), tantalum (Ta), tungsten (W), palladium (Pd), zirconium (Zr), platinum (Pt), aluminum (Al), and/or an alloy thereof selected based on the Dzyaloshinskii-Moriya interaction with the first free layer 121a and the second free layer 121b.

In this structure, the first free layer 121a and the second free layer 121b may form an antiferromagnet through the antiferromagnetic coupling layer 124. In other words, the free layer 121′ may have a stable state when a magnetization direction of the first free layer 121a and a magnetization direction of the second free layer 121b are opposite to each other.

The magnetic memory device 100b having the above-described structure may also be applied to a racetrack memory. The racetrack memory is a memory in which a plurality of domain walls are arranged in a layer direction (e.g., the X direction) inside the free layer 121′ and data is recorded by using the movement of a magnetic wall. The racetrack memory may store multi-bit data by using a plurality of magnetic walls of the free layer 121′. To form the plurality of magnetic walls, the free layer 121′ may be formed relatively long in the layer direction (e.g., the X direction). Even in the racetrack memory, because the magnetic wall is moved by using the spin current generated by the SOT layer 110, when a SHC increases, an operating current may be reduced. Therefore, the operating current of the racetrack memory may be reduced through the relatively large spin current generated in the SOT layer 110 including the OHC material layer 111 and the conversion layer 112.

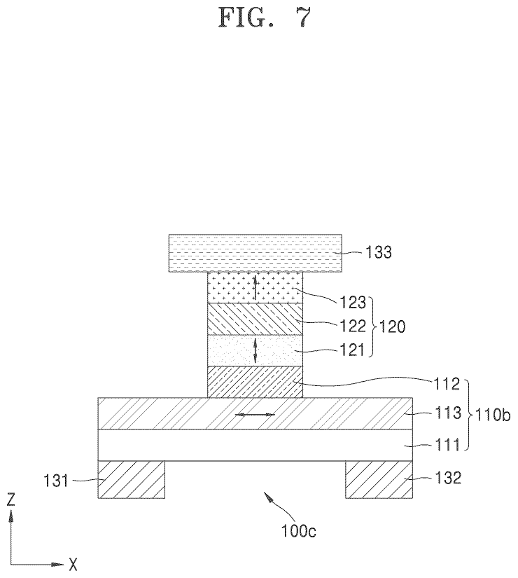

FIG. 7 is a cross-sectional view illustrating a schematic configuration of a magnetic memory device 100c according to at least one embodiment. Referring to FIG. 7, the SOT layer 110b of the magnetic memory device 100c may further include an in-plane magnetic anisotropy layer 113 provided between the OHC material layer 111 and the conversion layer 112. In other words, the SOT layer 110b may include the OHC material layer 111, the in-plane magnetic anisotropy layer 113 provided on the OHC material layer 111, and the conversion layer 112 provided on the in-plane magnetic anisotropy layer 113.

The in-plane magnetic anisotropy layer 113 may include a ferromagnetic metal material. For example, the in-plane magnetic anisotropy layer 113 may include a ferromagnetic metal material including at least one of cobalt (Co), iron (Fe), nickel (Ni), CoFe, FeB, CoFeB, and/or CoB. The in-plane magnetic anisotropy layer 113 may be configured such that a magnetization direction of the ferromagnetic material is fixed in a plane direction (e.g., the X direction or a horizontal direction). In this case, a spin current in a direction perpendicular to the plane direction or in the thickness direction (e.g., the Z direction) may be generated near an interface between the in-plane magnetic anisotropy layer 113 and the conversion layer 112. Then, when performing magnetic switching on the free layer 121, it is not necessary to apply a separate external magnetic field in the horizontal direction. In this regard, it may be seen that the in-plane magnetic anisotropy layer 113 serves as an external magnetic field. Thus, the magnetic memory device 100c may be configured to field-free switch without requiring the external magnetic field, e.g., when performing magnetic switching on the free layer 121 by using the in-plane magnetic anisotropy layer 113.

FIG. 7 illustrates that the magnetic memory device 100c includes the SOT layer 110 shown in FIG. 1, but the examples of FIG. 7 are not limited thereto, and, e.g., the magnetic memory device 100c may include the SOT layer 110a shown in FIG. 2.

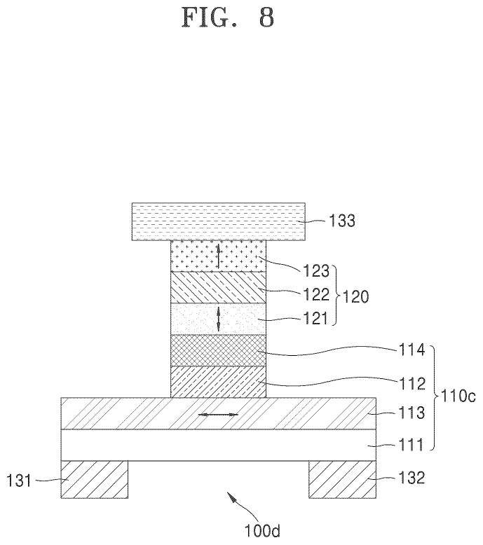

FIG. 8 is a cross-sectional view illustrating a schematic configuration of a magnetic memory device 100d according to at least one embodiment. Referring to FIG. 8, a SOT layer 110c of the magnetic memory device 100d may further include an insertion layer 114 provided on the conversion layer 112. The remaining configuration of the magnetic memory device 100d may be the same as the configuration of the magnetic memory device 100c shown in FIG. 7. Therefore, the SOT layer 110c may include the OHC material layer 111, the in-plane magnetic anisotropy layer 113 provided on the OHC material layer 111, the conversion layer 112 provided on the in-plane magnetic anisotropy layer 113, and the insertion layer 114 provided on the conversion layer 112. In other words, the insertion layer 114 may be provided between the conversion layer 112 and the tunneling magnetoresistance layer 120, especially between the conversion layer 112 and the free layer 121 of the tunneling magnetoresistance layer 120.

When the in-plane magnetic anisotropy layer 113 is present near the free layer 121 having perpendicular magnetic anisotropy (PMA), the PMA of the free layer 121 may be weakened. Therefore, the insertion layer 114 may serve to enhance the PMA of the free layer 121. To this end, the insertion layer 114 may include a metal material selected to enhance the PMA of the free layer 121. For example, the insertion layer 114 may include at least one of tungsten (W), tantalum (Ta), molybdenum (Mo), rhenium (Re), iridium (Ir), and ruthenium (Ru), and/or an alloy thereof selected based on the material of the free layer 121.

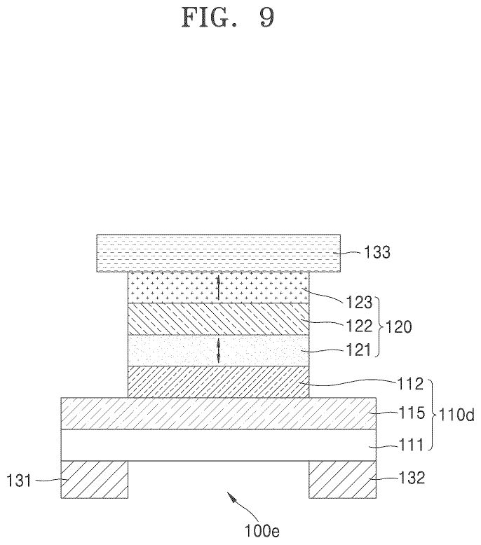

FIG. 9 is a cross-sectional view illustrating a schematic configuration of a magnetic memory device 100e according to at least one embodiment. Referring to FIG. 9, a SOT layer 110d of the magnetic memory device 100e may further include an SHC material layer 115 disposed between the OHC material layer 111 and the conversion layer 112. Therefore, the SOT layer 110d may include the OHC material layer 111, the SHC material layer 115 provided on the OHC material layer 111, and the conversion layer 112 provided on the SHC material layer 115. FIG. 9 illustrates that the magnetic memory device 100e includes the SOT layer 110 shown in FIG. 1, but the examples of FIG. 9 are not limited thereto, and, e.g., the magnetic memory device 100e may include the SOT layer 110a shown in FIG. 2.

The SHC material layer 115 may include a metal material having a relatively large SHC. The relatively large SHC of the SHC material layer 115 may additionally generate a spin current due to the spin Hall effect. Therefore, the spin current generated in the SOT layer 110d may be further increased through a combination of the OHC material layer 111 and the SHC material layer 115. The SHC material layer 115 may include, for example, tungsten (W) and/or tungsten (BW) having a beta (B) phase. The OHC material layer 111 may include, for example, at least one of iridium (Ir), manganese (Mn), vanadium (V), chromium (Cr), niobium (Nb), molybdenum (Mo), ruthenium (Ru), tantalum (Ta), and rhenium (Re), and/or an alloy thereof. The OHC material layer 111 may include, for example, chromium (Cr).

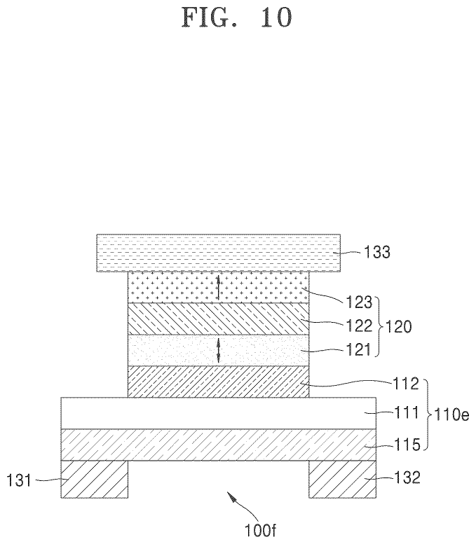

FIG. 10 is a cross-sectional view illustrating a schematic configuration of a magnetic memory device 100f according to at least one embodiment. FIG. 9 illustrates that the SHC material layer 115 is provided between the OHC material layer 111 and the conversion layer 112, but the disclosure is not limited thereto, and positions of the OHC material layer 111 and the SHC material layer 115 may be exchanged, as shown in FIG. 10. Referring to FIG. 10, a SOT layer 110e of the magnetic memory device 100f may further include the SHC material layer 115 provided below the OHC material layer 111. Therefore, the SOT layer 110e may include the SHC material layer 115, the OHC material layer 111 provided on the SHC material layer 115, and the conversion layer 112 provided on the OHC material layer 111. In this case, the SHC material layer 115 may be provided on the opposite side of the conversion layer 112 with respect to the OHC material layer 111. In other words, the OHC material layer 111 may have a first surface (e.g., an upper surface) and a second surface (e.g., a lower surface) facing the first surface, the conversion layer 112 may be provided on the first surface of the OHC material layer 111, and the SHC material layer 115 may be provided on the second surface of the OHC material layer 111.

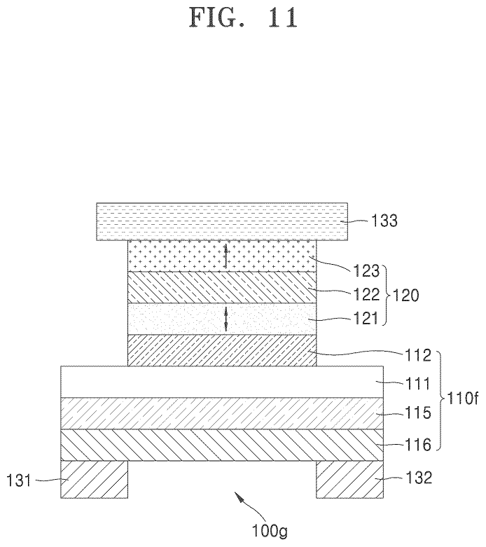

FIG. 11 is a cross-sectional view illustrating a schematic configuration of a magnetic memory device 100g according to at least one embodiment. When the SHC material layer 115 includes tungsten (βW) having a beta (β) phase, a seed layer for promoting formation of tungsten (βW) having the beta (β) phase may be further provided. Additionally, in at least some embodiments, a ratio of tungsten (βW) having the beta (β) phase and tungsten in the SHC material layer 115 may be controlled such that the SHC material layer 115 possesses the spin Hall effect associated with the tungsten (βW) having the beta (β) phase (and not, e.g., with tungsten having, e.g., an alpha (a) phase) without the higher resistivity associated with the tungsten (βW) having the beta (β). Referring to FIG. 11, a SOT layer 110f of the magnetic memory device 100g may further include a seed layer 116 provided below the SHC material layer 115. In other words, the SOT layer 110f may include the seed layer 116, the SHC material layer 115 provided on the seed layer 116, the OHC material layer 111 provided on the SHC material layer 115, and the conversion layer 112 provided on the OHC material layer 111. Accordingly, the SHC material layer 115 may be provided between the seed layer 116 and the OHC material layer 111. The SHC material layer 115 may include tungsten (βW) having the beta (β) phase. The seed layer 116 may include a material selected to promote the formation of tungsten (βW) having the beta (β) phase. For example, the seed layer 116 may include at least one of TaN, MgO, and/or CoFeB. In such cases, the seed layer 116 serves to maintain the stability of the metastable beta (β) phase in the seed layer 116. The seed layer 116 may, thereby, increase of tungsten (βW) having the beta (β) phase and tungsten (W) and/or the potential processing temperatures of the magnetic memory device 100g.

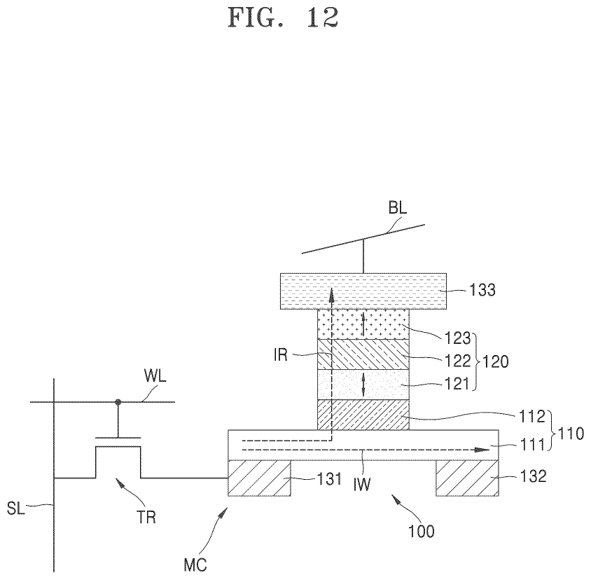

FIG. 12 schematically shows one magnetic memory cell including the magnetic memory device 100 according to at least one embodiment. Referring to FIG. 12, a memory cell MC may include the magnetic memory device 100 and a switching device TR connected thereto. The switching device TR may be a thin film transistor. The memory cell MC may be connected between a bit line BL and a word line WL. The bit line BL and the word line WL may be disposed to cross each other, and the memory cell MC may be disposed at an intersection of the bit line BL and the word line WL. The bit line BL may be electrically connected to the third electrode 133 of the magnetic memory device 100, and the word line WL may be connected to a gate of the switching device TR. In addition, a first source/drain electrode of the switching device TR may be electrically connected to the first electrode 131 of the magnetic memory device 100, and a second source/drain electrode may be electrically connected to a source line SL. FIG. 12 illustrates that the memory cell MC includes the magnetic memory device 100 shown in FIG. 1, but the memory cell MC in other embodiments may include one of the magnetic memory devices 100a to 100g shown in FIGS. 2 and 6 to 11.

In this structure, a write current IW or a read current IR may be applied to the memory cell MC through the word line WL, the source line SL, and the bit line BL. For example, when a voltage higher than a threshold voltage is applied to the word line WL and a current higher than a threshold current is applied to the source line SL, the switching device TR may be turned on, and the write current IW may flow through a path between the first electrode 131 and the second electrode 132 of the magnetic memory device 100. At this time, the second electrode 132 of the magnetic memory device 100 may be grounded. Then, a magnetization direction of the free layer 121 may be changed into the +Z direction or the −Z direction according to a direction of the current applied to the SOT layer 110.

Additionally, the read current IR may flow from the first electrode 131 of the magnetic memory device 100 to the bit line BL through the third electrode 133. For example, when the voltage higher than the threshold voltage is applied to the word line WL and a current lower than a threshold current is applied to the source line SL, the switching device TR may be turned on, and the read current IR may flow to the bit line BL through the first electrode 131 and the third electrode 133 of the magnetic memory device 100. At this time, the second electrode 132 of the magnetic memory device 100 may be in a floating state. Then, a resistance value of the magnetic memory device 100 may be read by measuring the current flowing through the bit line BL.

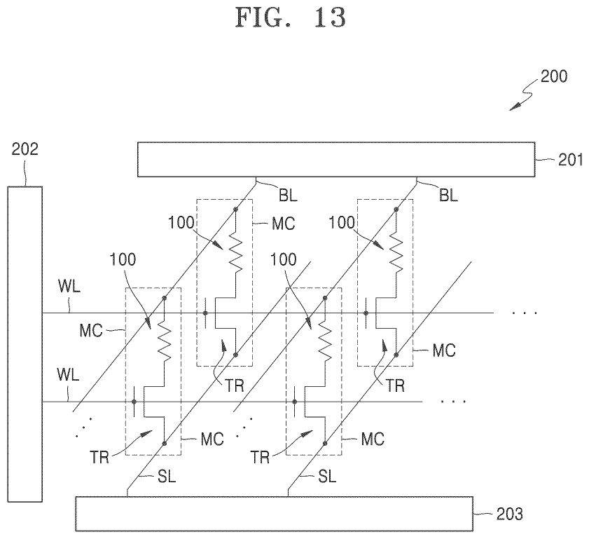

FIG. 13 is a circuit diagram schematically illustrating a configuration of a memory device 200 including the plurality of memory cells MCs shown in FIG. 12. Referring to FIG. 13, the memory device 200 may include a plurality of bit lines BL, a plurality of word lines WL, a plurality of selection lines SL, the plurality of memory cells MCs respectively disposed in intersection points of the plurality of bit lines BL and the plurality of word lines WL, a bit line driver 201 applying current to the plurality of bit lines BL, a word line driver 202 applying current to the plurality of word lines WL and a selection line driver 203 applying current to the plurality of selection lines SL. Each memory cell MC may have the configuration shown in FIG. 12. The memory device 200 shown in FIG. 13 may be, for example, a SOT-MRAM or a racetack memory, and may be used in electronic devices using a nonvolatile memory.

The above-described memory device 200 and/or the above-described magnetic memory devices 100 to 100g shown in FIGS. 1 to 2 and 6 to 11 may be used for data storage in various electronic devices.

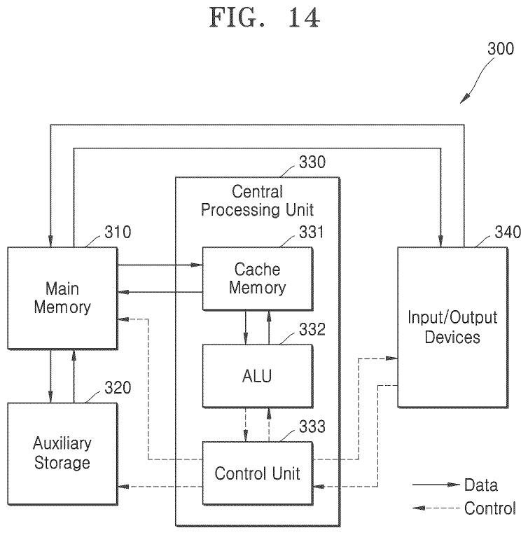

FIG. 14 is a conceptual diagram schematically illustrating a device architecture applicable to an electronic device 300. Referring to FIG. 14, the electronic device 300 may include a main memory 310, an auxiliary storage 320, a central processing unit (CPU) 330, and an input/output device 340. The CPU 330 may include a cache memory 331, an arithmetic logic unit (ALU) 332, and a control unit 333. The cache memory 331 may include static random-access memory (SRAM). The main memory 310 may include a DRAM device, and the auxiliary storage 320 may include the memory device 200 according to at least one embodiment. Alternatively, one or more of the cache memory 331, the main memory 310, and the auxiliary storage 320 may include the memory device 200 according to at least one embodiment.

It should be understood that the example embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A magnetic memory device comprising:
a tunneling magnetoresistance layer comprising a free layer, a tunneling barrier layer, and a pinned layer; and
a spin orbit torque (SOT) layer configured to provide a spin current, the spin current configured to change a magnetization direction of the free layer of the tunneling magnetoresistance layer,
wherein the SOT layer comprises
an orbital Hall conductance (OHC) material layer configured to provide an orbital Hall current, and
a conversion layer configured to convert the orbital Hall current into the spin current, and
wherein the OHC material layer comprises at least one of iridium (Ir), manganese (Mn), vanadium (V), chromium (Cr), niobium (Nb), molybdenum (Mo), ruthenium (Ru), tantalum (Ta), tungsten (W), or rhenium (Re).

2. The magnetic memory device of claim 1, wherein the OHC material layer includes at least one of IrMn or PtMn.

3. The magnetic memory device of claim 1, wherein the conversion layer includes at least one of platinum (Pt), terbium (Tb), gadolinium (Gd), samarium (Sm), or dysprosium (Dy).

4. The magnetic memory device of claim 1, wherein
the conversion layer is between the OHC material layer and the tunneling magnetoresistance layer, and
the free layer of the tunneling magnetoresistance layer is between the conversion layer and the tunneling barrier layer.

5. The magnetic memory device of claim 1, wherein
the SOT layer further includes an in-plane magnetic anisotropy layer between the OHC material layer and the conversion layer,
the free layer and the pinned layer each have perpendicular magnetic anisotropy (PMA), and
the in-plane magnetic anisotropy layer has in-plane magnetic anisotropy.

6. The magnetic memory device of claim 5, wherein the in-plane magnetic anisotropy layer includes at least one of cobalt (Co), iron (Fe), nickel (Ni), CoFe, FeB, CoFeB, or CoB.

7. The magnetic memory device of claim 5, wherein
the SOT layer further includes an insertion layer provided between the conversion layer and the tunneling magnetoresistance layer, and
the insertion layer includes at least one of tungsten (W), tantalum (Ta), molybdenum (Mo), rhenium (Re), iridium (Ir), or ruthenium (Ru).

8. The magnetic memory device of claim 1, wherein
the SOT layer further includes a spin Hall conductance (SHC) material layer between the OHC material layer and the conversion layer, the SHC material layer configured to generate the spin current due to a spin Hall effect,
the OHC material layer includes chromium (Cr), and
the SHC material layer includes at least one of tungsten (W) or tungsten (βW) with a beta (β) phase.

9. The magnetic memory device of claim 1, wherein
the SOT layer further includes a spin Hall conductance (SHC) material layer configured to generate the spin current due to a spin Hall effect,
the conversion layer is between the SHC material layer and the OHC material layer,
the OHC material layer includes chromium (Cr), and
the SHC material layer includes at least one of tungsten (W) or tungsten (βW) with a beta (β) phase.

10. The magnetic memory device of claim 9, wherein
the SOT layer further includes a seed layer configured to promote the beta (β) phase in the SHC material layer, and
the SHC material layer is between the seed layer and the OHC material layer.

11. The magnetic memory device of claim 10, wherein the seed layer includes at least one of TaN, MgO, and CoFeB.

12. The magnetic memory device of claim 1, wherein
the free layer includes a first free layer, a second free layer, and an antiferromagnetic coupling layer between the first free layer and the second free layer, and
a magnetization direction of the first free layer is opposite to a magnetization direction of the second free layer.

13. The magnetic memory device of claim 12, wherein the antiferromagnetic coupling layer includes at least one of ruthenium (Ru), iridium (Ir), tantalum (Ta), tungsten (W), palladium (Pd), zirconium (Zr), platinum (Pt), or aluminum (Al).

14. The magnetic memory device of claim 1, further comprising:
a first electrode and a second electrode spaced apart from each other, the first electrode and second electrode configured to provide a write current between the first electrode and second electrode and through the SOT layer; and
a third electrode electrically connected to the pinned layer such that the third electrode and at least one of the first electrode or the second electrode are configured to provide a read current through the tunneling magnetoresistance layer and the SOT layer.

15. A memory device comprising:
a plurality of memory cells, each of the plurality of memory cells comprising a magnetic memory device and a switching device connected to the magnetic memory device,
wherein the magnetic memory device comprises
a tunneling magnetoresistance layer comprising a free layer, a tunneling barrier layer, and a pinned layer, and
a spin orbit torque (SOT) layer configured to provide a spin current, the spin current configured to change a magnetization direction of the free layer of the tunneling magnetoresistance layer,
wherein the SOT layer comprises
an orbital Hall conductance (OHC) material layer configured to provide an orbital Hall current, and
a conversion layer configured to convert the orbital Hall current into the spin current, and
wherein the OHC material layer comprises at least one of iridium (Ir), manganese (Mn), vanadium (V), chromium (Cr), niobium (Nb), molybdenum (Mo), ruthenium (Ru), tantalum (Ta), tungsten (W), or rhenium (Re).

16. The memory device of claim 15, wherein the conversion layer includes at least one of platinum (Pt), terbium (Tb), gadolinium (Gd), samarium (Sm), or dysprosium (Dy).

17. The memory device of claim 15, wherein
the SOT layer further includes an in-plane magnetic anisotropy layer between the OHC material layer and the conversion layer,
the free layer and the pinned layer each have perpendicular magnetic anisotropy (PMA),
the in-plane magnetic anisotropy layer has in-plane magnetic anisotropy, and
the in-plane magnetic anisotropy layer includes at least one of cobalt (Co), iron (Fe), nickel (Ni), CoFe, FeB, CoFeB, or CoB.

18. The memory device of claim 17, wherein the SOT layer further includes an insertion layer between the conversion layer and the tunneling magnetoresistance layer, and
the insertion layer includes at least one of tungsten (W), tantalum (Ta), molybdenum (Mo), rhenium (Re), iridium (Ir), or ruthenium (Ru).

19. The memory device of claim 15, wherein
the SOT layer further includes a spin Hall conductance (SHC) material layer between the OHC material layer and the conversion layer, the SHC material layer configured to generate the spin current due to a spin Hall effect, the OHC material layer includes chromium (Cr), and
the SHC material layer includes at least one of tungsten (W) or tungsten (βW) with a beta (β) phase.

20. The memory device of claim 15, wherein
the SOT layer further includes a spin Hall conductance (SHC) material layer configured to generate the spin current due to a spin Hall effect,
the conversion layer is between the SHC material layer and the OHC material layer,
the OHC material layer includes chromium (Cr), and
the SHC material layer includes tungsten (βW) or tungsten (βW) with a beta (β) phase.
